(19) United States
(12) Patent Application Publication
(10) Pub. No.: US 2025/0046637 A1
(43) Pub. Date: Feb. 6, 2025

(54) AUTOMATIC CORRECTION DEVICE OF ROBOTIC ARM AND METHOD THEREOF

(71) Applicant: JUN-FU TECHNOLOGY INC, New Taipei City (TW)

(72) Inventors: Cheng-Hsiang LU, New Taipei City (TW); Chung-Hsien LU, New Taipei City (TW); Yu-Hsin LIU, New Taipei City (TW); Jen-Wei CHANG, New Taipei City (TW); Jyun-Yi LU, New Taipei City (TW); Bo-Wen LIN, New Taipei City (TW)

(21) Appl. No.: 18/365,238

(22) Filed: Aug. 4, 2023

(51) Int. Cl. H01L 21/67; B25J 9/16; B65G 47/90; H01L 21/687

(52) U.S. Cl. CPC H01L 21/67265; B25J 9/1653; B25J 9/1692; B65G 47/905; H01L 21/67288; H01L 21/68707

(57) ABSTRACT

A device and a method for robotic arm automatic correction are disclosed. A main structure includes a robotic arm including an optical photographing mechanism, and a wafer storage mechanism at one side of the robotic arm and including a graphic data code. The optical photographing mechanism is in information connection with an optical recognition module that includes a data code analysis unit, an object distance analysis unit, and a wafer center analysis unit. A user uses the optical photographing mechanism to photograph the graphic data code for implementing a first round of position correction for the robotic arm. Then, the optical photographing mechanism photographs a wafer and performs an operation of focusing for calculation of a distance between the robotic arm and a center point of the wafer by means of the object distance analysis unit in combination with the wafer center analysis unit for a second round of correction.

### TECHNICAL FIELD OF THE INVENTION

The present invention provides an automatic correction device of a robotic arm that implements a fast and accurate operation of correction, and a method thereof.

### DESCRIPTION OF THE PRIOR ART

The structure and fabrication of a semiconductor wafer are delicate and sophisticated, and consequently, requirements for storage and shipping are relatively severe. To store wafers, dedicated storage carriers must be used for disposition and storage, in order to suit to various types of storage conditions, such as storage in vacuum or storage with introduction of inert gas. To ship wafers, a carrier, in addition to being directly transporting, needs to be opened for removal of wafers, and a robotic arm is often employed to remove the wafers from the interior, in order to prevent situations of wafer breaking or damaging during transporting.

Before the removal or disposition is conducted with the robotic arm, the distance between the robotic arm and the wafer carrier must be first positioned completely in order to correctly carry out the operation of removal or disposition. The operation of positioning can be done in an automatic fashion or a manual operation is implemented to conduct the operation of removal or disposition. For the manual operation, visual inspection or machine measurement can be implemented to provide related distance data for assisting a user to conduct the positioning operation of the robotic arm. For an operation of removal or disposition performed with an automatic robotic arm, multiple sensors are applied in combination with various fashions of measurement in order to allow the robotic arm to correctly carry out the operation of positioning.

If the operation of positioning is not accurate, then various situations may occur in the operation of removal or disposition by the robotic arm, and thus, the chance of defective products is heightened. However, to carry out a positioning operation correctly, a large number of sensors must be involved, and this increases the cost of operation.

### SUMMARY OF THE INVENTION

The primary objective of the present invention is to achieve an effect of easy and accurate correction by using an optical photographing mechanism.

To achieve the above objective, a main structure of the present invention comprises: a robotic arm, a wafer storage mechanism arranged at one side of the robotic arm, a graphic data code arranged on the wafer storage mechanism, an optical photographing mechanism arranged on the robotic arm, an optical recognition module in information connection with the optical photographing mechanism, a data code analysis unit arranged in the optical recognition module, an object distance analysis unit arranged in the optical recognition module, and a wafer center analysis unit arranged in the optical recognition module.

By means of the above structure, when a user uses the robotic arm to remove a wafer, the robotic arm may automatically carry out a correction operation. Firstly, the optical photographing mechanism photographs the graphic data code, and the data code analysis unit analyze the graphic data code to retrieve corresponding position data so as to allow the robotic arm to implement a first round of correction operation.

By performing the first round of correction operation, an approximate position of the wafer storage mechanism can be learned, and at this moment, the optical photographing mechanism is applied to photograph and focus on one of the wafers in the wafer storage mechanism, in order to allow the object distance analysis unit to calculate a wafer distance between the optical photographing mechanism and the wafer by means of a focal length of a lens of the optical photographing mechanism and a distance between the lens and a photoreception imaging position in the optical photographing mechanism. After the calculation of the wafer distance, the wafer center analysis unit is applied to calculate a distance between the robotic arm and a center point of the wafer by means of a distance between the robotic arm and the optical photographing mechanism, the wafer distance, and a width of the wafer, by which a second round of correction operation can be achieved for realizing a complete effect of correction, and afterwards, an operation of picking and placing a wafer can be performed.

As such, by means of the above-described way, the robotic arm can fast and accurately fulfill a correction operation, which can be realized by only using an operation of photographing, and thus, the correction operation can be completely and fast fulfilled with a reduced cost.

By means of the technology described above, the problem that the prior art way of correction is of a high cost or poor accuracy can be overcome, thereby realizing practical progress for the above-discussed advantages.

### BRIEF DESCRIPTION OF THE DRAWINGS

FIG. 1 is a perspective view showing a preferred embodiment of the present invention.

FIG. 2 is a structure block diagram of the preferred embodiment of the present invention.

FIG. 3 is a flow chart of the preferred embodiment of the present invention.

FIG. 4 is a schematic view illustrating photographing according to the preferred embodiment of the present invention.

FIG. 5 is a schematic view illustrating a focal length according to the preferred embodiment of the present invention.

FIG. 6 is a schematic view illustrating center calculating according to the preferred embodiment of the present invention.

FIG. 7 is a perspective view showing another preferred embodiment of the present invention.

FIG. 8 is a flow chart of said another preferred embodiment of the present invention.

FIG. 9 is a schematic view illustrating warpage inspecting according to said another preferred embodiment of the present invention.

FIG. 10 is a perspective view showing a further preferred embodiment of the present invention.

FIG. 11 is a flow chart of said further preferred embodiment of the present invention.

FIG. 12 is a schematic view illustrating spacing distance detecting according to said further preferred embodiment of the present invention.

FIG. 13 is a perspective view showing yet a further preferred embodiment of the present invention

FIG. 14 is a flow chart of said yet a further preferred embodiment of the present invention.

### DETAILED DESCRIPTION OF THE PREFERRED EMBODIMENT

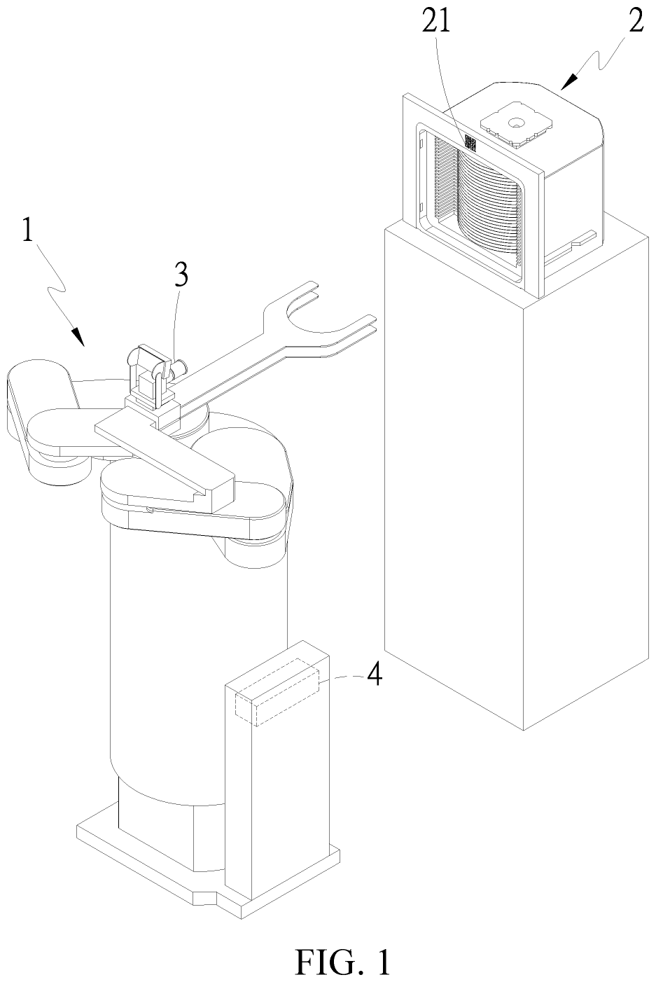

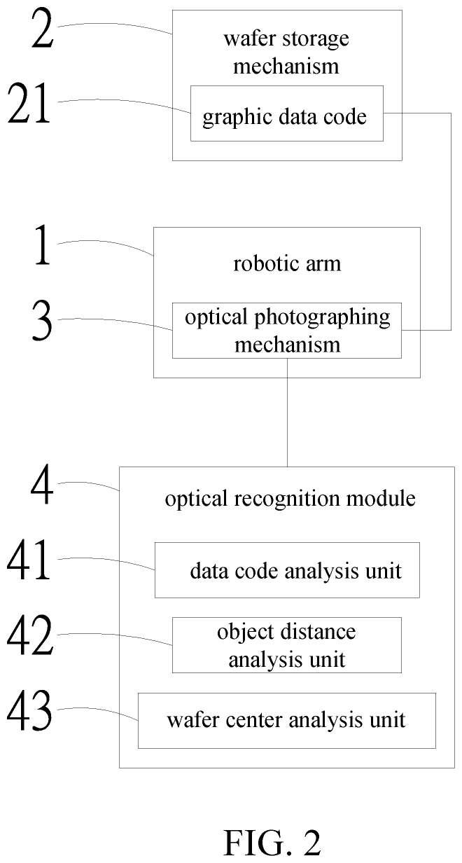

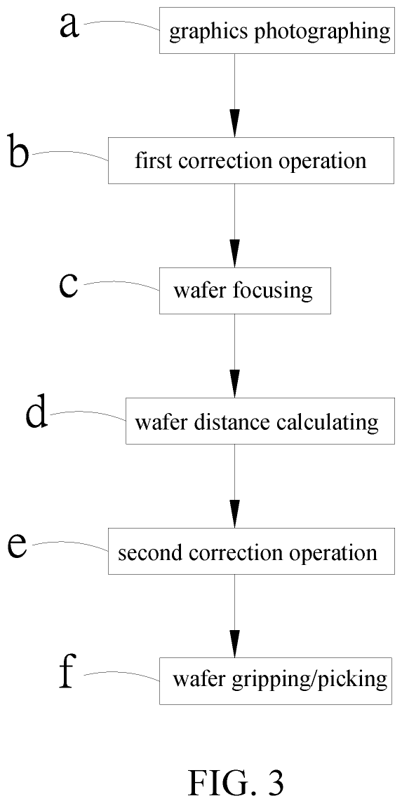

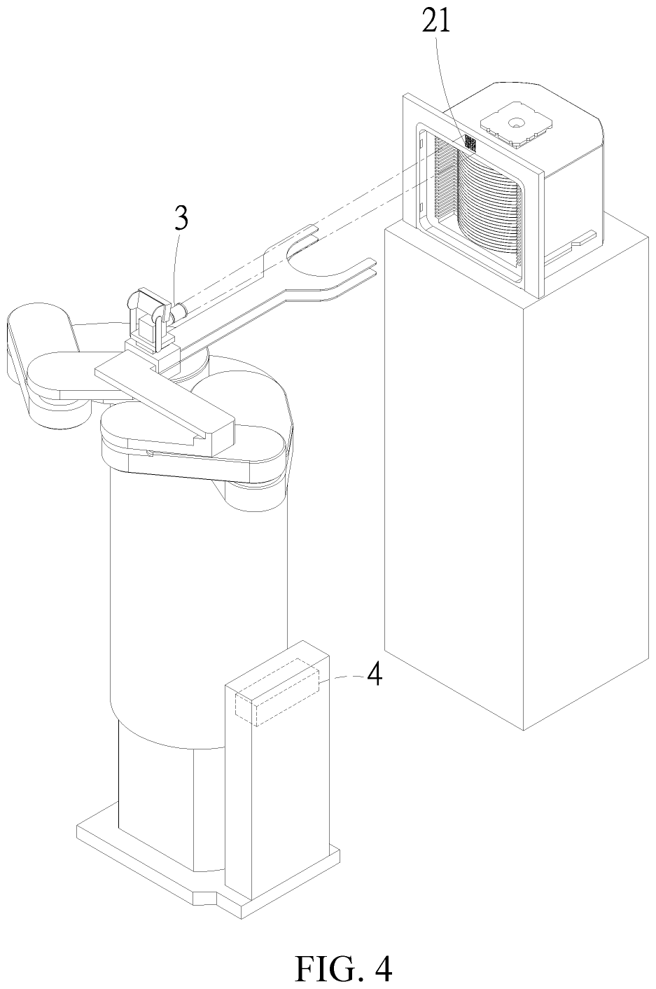

Referring to FIGS. 1-6, which are a perspective view to a schematic view of center calculating according to a preferred embodiment of the present invention, it can be clearly seen from the drawings that the present invention includes:
a robotic arm 1, wherein a robotic arm 1 that is computer controllable to pick/place and move a wafer is taken as an example;
a wafer storage mechanism 2, which is arranged at one side the robotic arm 1, wherein a storage device for storing a wafer is taken as an example;
a graphic data code 21, which is arranged on the wafer storage mechanism 2, wherein a quick response (QR) code is taken as an example;
an optical photographing mechanism 3, which is arranged on the robotic arm 1, wherein in the instant embodiment, the optical photographing mechanism 3 includes a camera that includes a charge-coupled device (CCD);
an optical recognition module 4, which is in information connection with the optical photographing mechanism 3 and the robotic arm 1, wherein a processor that is connected with the optical photographing mechanism 3 and receives a photographed image is taken as an example;
a data code analysis unit 41, which is arranged in the optical recognition module 4;
an object distance analysis unit 42, which is arranged in the optical recognition module 4; and
a wafer center analysis unit 43, which is arranged in the optical recognition module 4, wherein in the instant embodiment, software loaded in the optical recognition module 4 is taken as an example for each of the data code analysis unit 41, the object distance analysis unit 42, and the wafer center analysis unit 43.

Based on the above description, the structure of the technology of the present invention can be appreciated, and based on a corresponding combination of such a structure, an advantage of achieving a fast and accurate operation of correction with a reduced cost can be realized. A detailed explanation will be provided below.

Steps of a robotic arm automatic correction method according to the present invention include:
(a) graphics photographing: applying an optical photographing mechanism 3 on a robotic arm 1 to photograph a graphic data code 21 on a wafer storage mechanism 2;
(b) first correction operation: applying a data code analysis unit 41 of an optical recognition module 4 to analyze the graphic data code 21 to retrieve corresponding position data, in order to enable the robotic arm 1 to implement a first round of correction operation;
(c) wafer focusing: applying the optical photographing mechanism 3 to photograph and focus on one of wafers in the wafer storage mechanism 2;
(d) wafer distance calculating: applying an object distance analysis unit 42 in the optical recognition module 4 to calculate a wafer distance between the optical photographing mechanism 3 and the wafer by means of a focal length of a lens of the optical photographing mechanism 3 and a distance between the lens and a photoreception imaging position of the optical photographing mechanism 3;
(e) second correction operation: after the calculating of the wafer distance, applying a wafer center analysis unit 43 to calculate a distance between the robotic arm 1 and a center point of the wafer by means of a distance between the robotic arm 1 and the optical photographing mechanism 3, the wafer distance, and a width of the wafer to fulfill a second round of correction operation; and
(f) wafer gripping/picking: controlling, by means of the distance between the robotic arm 1 and the center point of the wafer, the robotic arm 1 to carry out a gripping/picking operation of the wafer.

It is known from the above steps that a user arranges the graphic data code 21 on the wafer storage mechanism 2 in advance, and when it needs for the robotic arm 1 to grip/pick a wafer, an operation of correction is first carried out in order to accurately grip/pick the wafer disposed inside the wafer storage mechanism 2.

As such, the optical photographing mechanism 3 can be applied first to photograph the graphic data code 21, and the data code analysis unit 41 of the optical recognition module 4 is then applied to analyze the graphic data code 21 to retrieve related position data (such as a relative direction of the wafer storage mechanism 2 with respect to the robotic arm 1), by which the first round of correction operation can be carried out.

After the performance of first correction operation, an approximate location of the wafer storage mechanism 2 can be aware, and then, the optical photographing mechanism 3 can be re-applied to photograph the wafer inside the wafer storage mechanism 2 and to focus on the wafer to be removed. At this moment, the object distance analysis unit 42 may carry out an operation of calculation and analysis by using a lens imaging formula (1/o+1/i=1/f), the formula being a known mathematic formula.

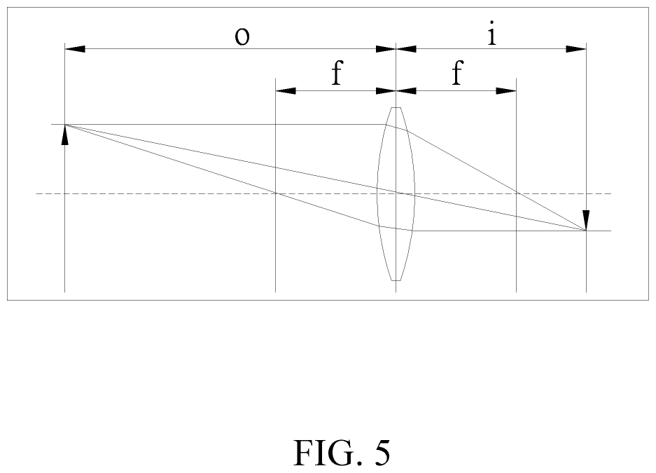

The calculation is demonstrated with reference to FIG. 5, wherein a distance between the lens of the optical photographing mechanism 3 and an object to be focused on (which is the wafer in this case) is “o”; a distance between the lens of the optical photographing mechanism 3 and the photoreception imaging position of the optical photographing mechanism 3 is “i”; a focal length of the lens of the optical photographing mechanism 3 is “f”, in which the focal length (f) of the lens of the optical photographing mechanism 3 is a known data when the lens is installed or purchased, and the distance (i) between the lens of the optical photographing mechanism 3 and the photoreception imaging position of the optical photographing mechanism 3 becomes a known distance after focusing, so that the distance “o” between the lens of the optical photographing mechanism 3 and the object to be focused on (the wafer in this case) can be calculated and, due to the lens being arranged at a frontmost end of the optical photographing mechanism 3, can be directly treated as the distance between the optical photographing mechanism 3 and the wafer, which is defined, in the invention, as “the wafer distance o”.

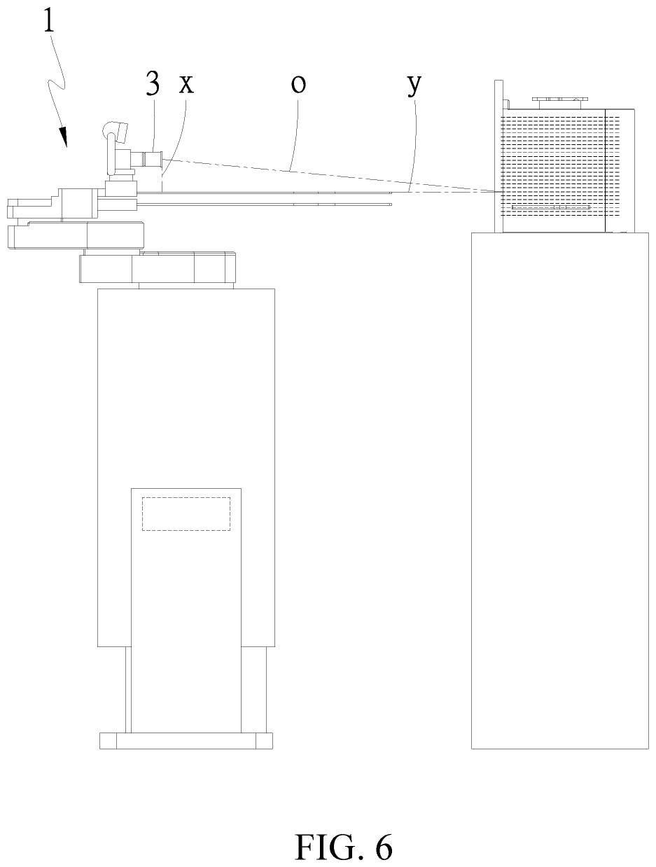

Referring to FIG. 6, after the wafer distance is calculated, due to the optical photographing mechanism 3 being directly mounted on a top side of the robotic arm 1, a vertical distance “x” between the optical photographing mechanism 3 and the robotic arm 1 can thus be directly aware, and consequently, based on the wafer distance “o” and the vertical distance “x” described above, the wafer center analysis unit 43 can calculate a distance “y” from the robotic arm 1 to an edge of the wafer (which is a positional point on which the optical photographing mechanism 3 is focused) by following the trigonometric formula (x²+y²=o²), and further, a radius (d) of the wafer is a data known before gripping/picking, but not limited thereto, such as the radius (d) being read and learned simultaneously with retrieval of the corresponding position data by the optical photographing mechanism 3 photographing the graphic data code 21 to be subsequently transmitted to the wafer center analysis unit 43. As such, the distance between the robotic arm 1 and the center point of the wafer can be learned from the distance “y” from the robotic arm 1 to the edge of the wafer in combination with the radius (d) of the wafer descried above, by which the second round of correction can be realized.

After the two rounds of correction, the robotic arm 1 is enabled to automatically calculate the distance between the robotic arm 1 and the wafer the center point for implementing an operation of gripping/picking. The entire process of correction can be completed with only an optical photographing mechanism 3 operated in combination with a graphic data code 21, together with calculation performed with an optical recognition module 4. As such, an effect of saving cost can be realized with a relatively simple structure, and the operation of the entirety can be done with only operations of photographing and related calculation, so that time and efficiency of correction can be greatly increased.

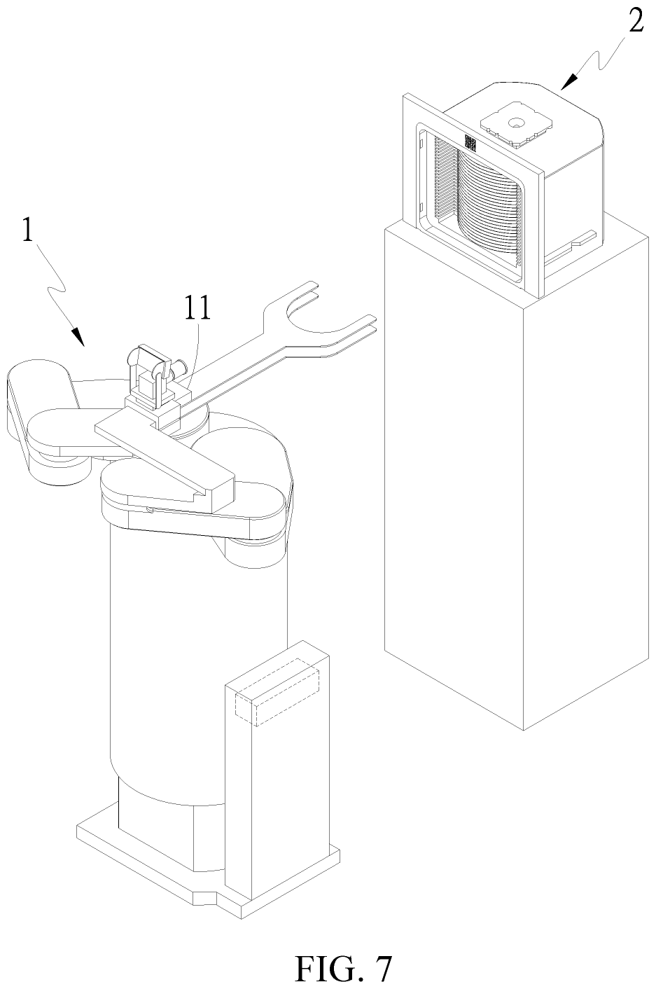

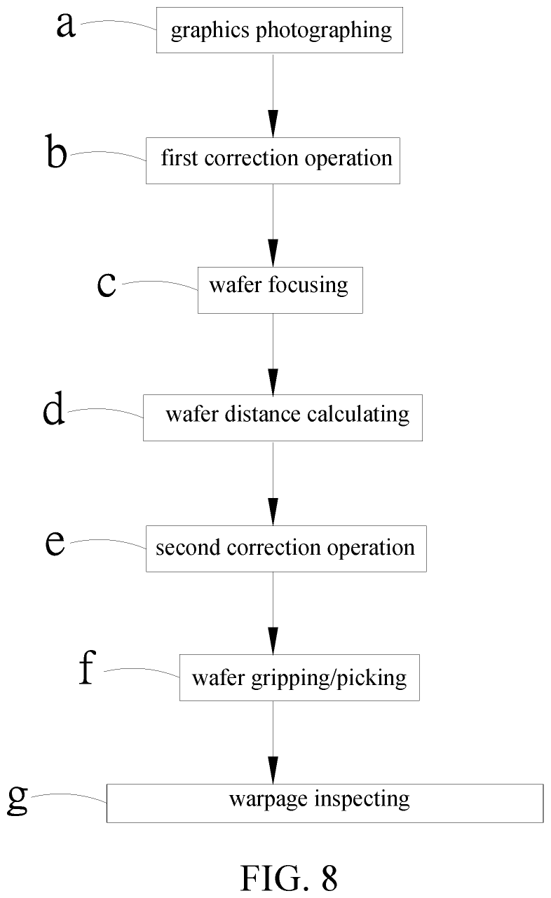

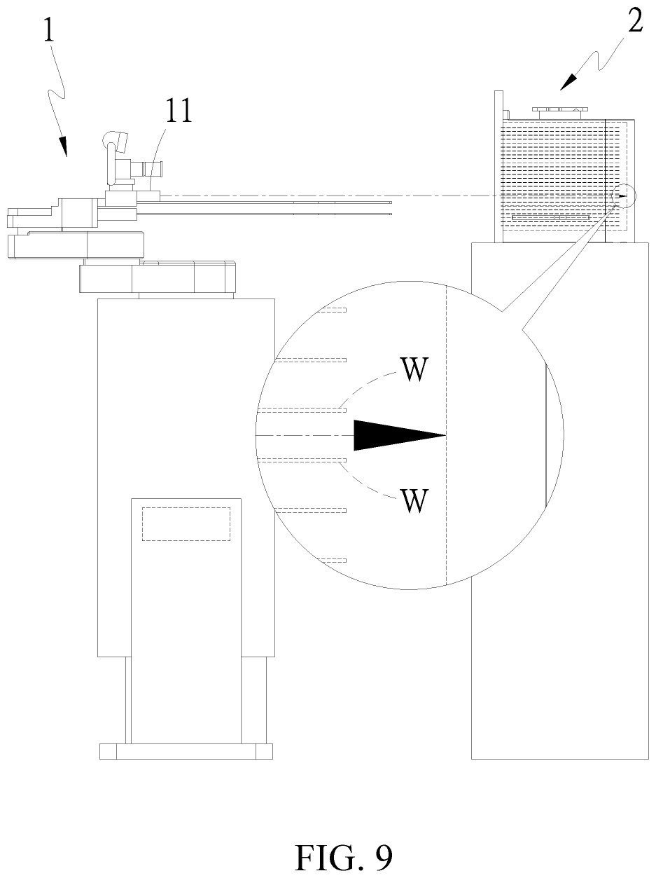

Referring to FIGS. 7-9, which are respectively a perspective view to a schematic view of warpage inspecting according to another preferred embodiment of the present invention, it can be clearly seen from the drawings that the instant embodiment is generally similar to the previous embodiment and is only such that the robotic arm 1 is provided with a warpage detector 11, wherein, in the instant embodiment, a laser detector is taken as an example for the warpage detector 11.

Steps of the instant embodiment include:
(a) graphics photographing: applying an optical photographing mechanism on a robotic arm 1 to photograph a graphic data code on a wafer storage mechanism 2;
(b) first correction operation: applying a data code analysis unit of an optical recognition module to analyze the graphic data code to retrieve corresponding position data, in order to enable the robotic arm 1 to implement a first round of correction operation;
(c) wafer focusing: applying the optical photographing mechanism to photograph and focus on one of wafers in the wafer storage mechanism;
(d) wafer distance calculating: applying an object distance analysis unit in the optical recognition module to calculate a wafer distance between the optical photographing mechanism and the wafer by means of a focal length of a lens of the optical photographing mechanism and a distance between the lens and a photoreception imaging position of the optical photographing mechanism;
(e) second correction operation: after the calculating of the wafer distance, applying a wafer center analysis unit to calculate a distance between the robotic arm 1 and a center point of the wafer by means of a distance between the robotic arm 1 and the optical photographing mechanism, the wafer distance, and a width of the wafer to fulfill a second round of correction operation;
(f) wafer gripping/picking: controlling, by means of the distance between the robotic arm 1 and the center point of the wafer, the robotic arm 1 to carry out a gripping/picking operation of the wafer; and
(g) warpage inspecting: applying a warpage detector 11 on the robotic arm 1 to inspect a state of warpage of the wafer.

As known from the previous embodiment, the distance from the robotic arm 1 to the center of the wafer has been calculated, and based on such a distance, it only needs to add a length of the radius of the wafer W to approximately estimate a distance from the robotic arm 1 to a bottom of the wafer storage mechanism 2, and if a length measured after rebounding of a laser emitting from the warpage detector 11 is smaller than such a distance, it can be determined that the wafer W warps and blocks a path of the laser from the warpage detector 11, and by such a measure, the chance that wafer breaking occurs on the wafer W due to impact with the warpage during gripping/picking can be reduced.

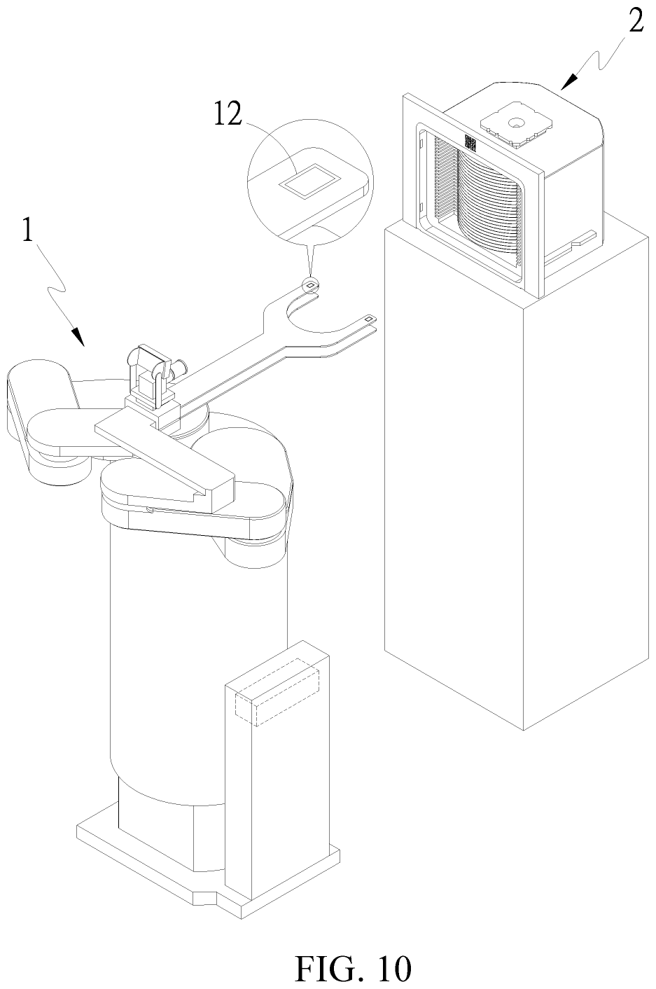

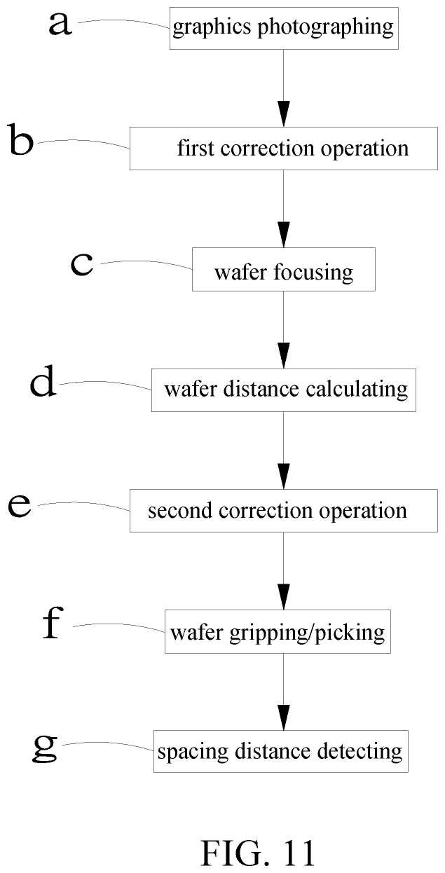

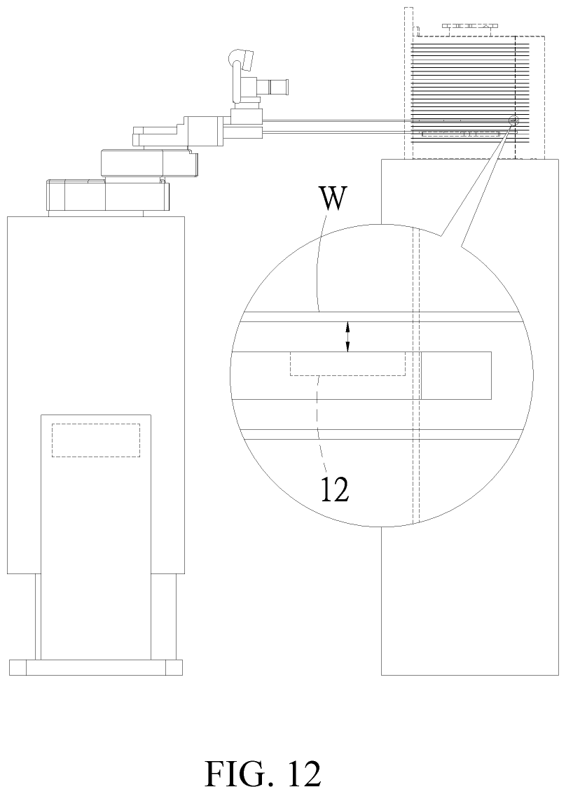

Referring to FIGS. 10-12, which are respectively a perspective view to a schematic view of spacing distance detecting according to a further preferred embodiment of the present invention, it can be clearly seen from the drawings that the instant embodiment is generally similar to the previous embodiments and is only such that the robotic arm 1 is provided with a distance detector 12 11, wherein, in the instant embodiment, a thinned distance sensor is taken as an example for the distance detector 12.

Steps of the instant embodiment include:
(a) graphics photographing: applying an optical photographing mechanism on a robotic arm 1 to photograph a graphic data code on a wafer storage mechanism;
(b) first correction operation: applying a data code analysis unit of an optical recognition module to analyze the graphic data code to retrieve corresponding position data, in order to enable the robotic arm to implement a first round of correction operation;
(c) wafer focusing: applying the optical photographing mechanism to photograph and focus on one of wafers in the wafer storage mechanism 2;
(d) wafer distance calculating: applying an object distance analysis unit in the optical recognition module to calculate a wafer distance between the optical photographing mechanism and the wafer by means of a focal length of a lens of the optical photographing mechanism and a distance between the lens and a photoreception imaging position of the optical photographing mechanism;
(e) second correction operation: after the calculating of the wafer distance, applying a wafer center analysis unit to calculate a distance between the robotic arm and a center point of the wafer by means of a distance between the robotic arm 1 and the optical photographing mechanism, the wafer distance, and a width of the wafer to fulfill a second round of correction operation;
(f) wafer gripping/picking: controlling, by means of the distance between the robotic arm 1 and the center point of the wafer, the robotic arm 1 to carry out a gripping/picking operation of the wafer; and
(g) spacing distance detecting: applying a distance detector 12 on the robotic arm 1 to detect a spacing distance between the wafer and the robotic arm 1.

When the robotic arm 1 is extended into the wafer storage mechanism 2 for performing the operation of gripping/picking, the distance detector 12 can be applied to detect a distance between upper-side and lower-side wafers W in order to prevent occurrence of impact resulting from an excessively small spacing distance therebetween.

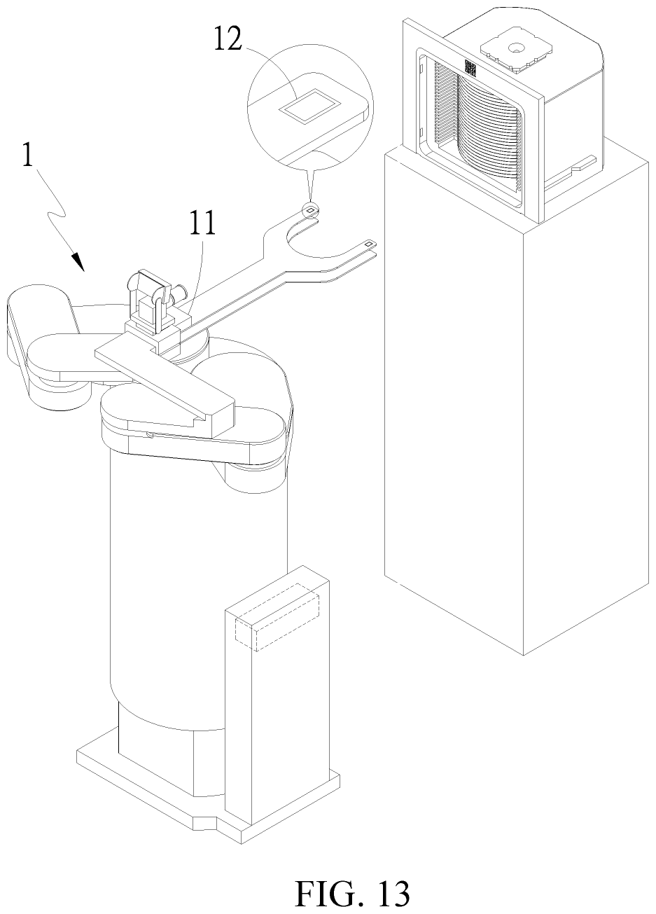

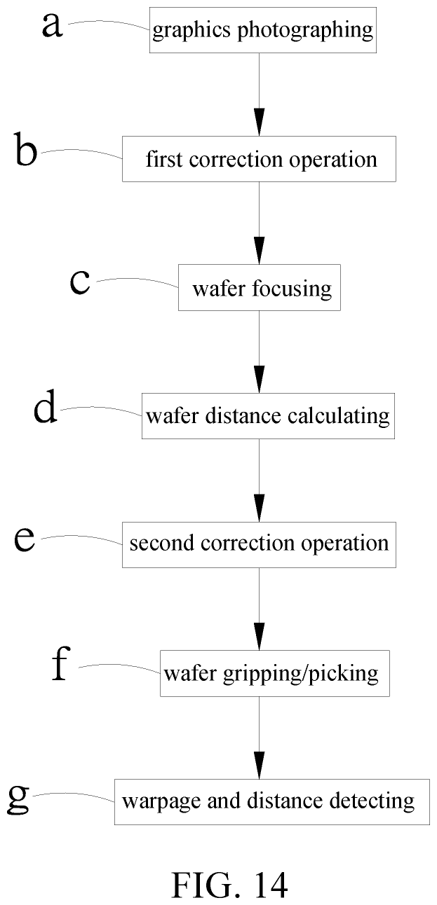

Referring to FIGS. 13 and 14, which are respectively a perspective view and a flow chart according to yet a further preferred embodiment of the present invention, it can be clearly seen from the drawings that the instant embodiment is generally similar to the previous embodiments and is only such that the robotic arm 1 is provided with both a distance detector 12 and a warpage detector 11.

Steps of the instant embodiment include:
(a) graphics photographing: applying an optical photographing mechanism on a robotic arm 1 to photograph a graphic data code on a wafer storage mechanism;
(b) first correction operation: applying a data code analysis unit of an optical recognition module to analyze the graphic data code to retrieve corresponding position data, in order to enable the robotic arm to implement a first round of correction operation;
(c) wafer focusing: applying the optical photographing mechanism to photograph and focus on one of wafers in the wafer storage mechanism 2;
(d) wafer distance calculating: applying an object distance analysis unit in the optical recognition module to calculate a wafer distance between the optical photographing mechanism and the wafer by means of a focal length of a lens of the optical photographing mechanism and a distance between the lens and a photoreception imaging position of the optical photographing mechanism;
(e) second correction operation: after the calculating of the wafer distance, applying a wafer center analysis unit to calculate a distance between the robotic arm and a center point of the wafer by means of a distance between the robotic arm 1 and the optical photographing mechanism, the wafer distance, and a width of the wafer to fulfill a second round of correction operation;
(f) wafer gripping/picking: controlling, by means of the distance between the robotic arm 1 and the center point of the wafer, the robotic arm 1 to carry out a gripping/picking operation of the wafer; and
(g) warpage and distance detecting: applying a warpage detector 11 on the robotic arm 1 to inspect a state of warpage of the wafer and applying a distance detector 12 on the robotic arm 1 to detect a spacing distance between the wafer and the robotic arm 1.

As such, the robotic arm 1 according to the present invention can possesses both effects of warpage inspecting and spacing distance detecting, and this suggests that the warpage detector 11 and the distance detector 12 can be installed together to enhance operation safety of the present invention.

I claim:

1. A robotic arm automatic correction device, mainly comprising:
a robotic arm;
a wafer storage mechanism, the wafer storage mechanism being arranged at one side of the robotic arm;
a graphic data code, the graphic data code being arranged on the wafer storage mechanism;
an optical photographing mechanism, the optical photographing mechanism being arranged on the robotic arm;
an optical recognition module, the optical recognition module being in information connection with the optical photographing mechanism and the robotic arm;
a data code analysis unit, the data code analysis unit being arranged in the optical recognition module and operable to analyze the graphic data code to retrieve corresponding position data;
an object distance analysis unit, the object distance analysis unit being arranged in the optical recognition module and in information connection with the data code analysis unit, the object distance analysis unit being operable to calculate a wafer distance between the optical photographing mechanism and a wafer in the wafer storage mechanism by means of a focal length of a lens of the optical photographing mechanism and a distance between the lens and a photoreception imaging position of the optical photographing mechanism; and
a wafer center analysis unit, the wafer center analysis unit being arranged in the optical recognition module and in information connection with the data code analysis unit, in order to calculate a distance between the robotic arm and a center point of the wafer by means of a distance between the robotic arm and the optical photographing mechanism, the wafer distance, and a width of the wafer.

2. The robotic arm automatic correction device according to claim 1, wherein the robotic arm is provided with a warpage detector arranged thereon.

3. The robotic arm automatic correction device according to claim 1, wherein the robotic arm is provided with a distance detector arranged thereon.

4. The robotic arm automatic correction device according to claim 1, wherein the object distance analysis unit is operable to carry out calculation and analysis by means of a lens imaging formula.

5. The robotic arm automatic correction device according to claim 1, wherein the wafer center analysis unit is operable to calculate the distance between the robotic arm and the center point of the wafer by adopting a trigonometric operation.

6. A robotic arm automatic correction method, of which steps include:
(a) applying an optical photographing mechanism on a robotic arm to photograph a graphic data code on a wafer storage mechanism;
(b) applying a data code analysis unit of an optical recognition module to analyze the graphic data code to retrieve corresponding position data, in order to enable the robotic arm to implement a first round of correction operation;
(c) applying the optical photographing mechanism to photograph and focus on one of wafers in the wafer storage mechanism;
(d) applying an object distance analysis unit in the optical recognition module to calculate a wafer distance between the optical photographing mechanism and the wafer by means of a focal length of a lens of the optical photographing mechanism and a distance between the lens and a photoreception imaging position of the optical photographing mechanism;
(e) after the calculating of the wafer distance, applying a wafer center analysis unit to calculate a distance between the robotic arm and a center point of the wafer by means of a distance between the robotic arm and the optical photographing mechanism, the wafer distance, and a width of the wafer to fulfill a second round of correction operation; and
(f) controlling, by means of the distance between the robotic arm and the center point of the wafer, the robotic arm to carry out a gripping/picking operation of the wafer.

7. The robotic arm automatic correction method according to claim 6, wherein after step (f), step (g) is performed, wherein a warpage detector on the robotic arm is applied to inspect a state of warpage of the wafer.

8. The robotic arm automatic correction method according to claim 6, wherein after step (f), step (g) is performed, wherein a distance detector on the robotic arm is applied to detect a spacing distance between the wafer and the robotic arm.

9. The robotic arm automatic correction method according to claim 6, wherein the object distance analysis unit carries out calculation and analysis by means of a lens imaging formula.

10. The robotic arm automatic correction method according to claim 6, wherein the wafer center analysis unit calculates the distance between the robotic arm and the center point of the wafer by adopting a trigonometric operation.
